(19) United States
(12) Patent Application Publication
(10) Pub. No.: US 2023/0240055 A1
(43) Pub. Date: Jul. 27, 2023

(54) METHODS AND APPARATUS TO MANAGE NOISE IN COMPUTING SYSTEMS

(71) Applicants: Francesc Guim Bernat, Barcelona (ES); Karthik Kumar, Chandler, AZ (US); Marcos Carranza, Portland, OR (US)

(72) Inventors: Francesc Guim Bernat, Barcelona (ES); Karthik Kumar, Chandler, AZ (US); Marcos Carranza, Portland, OR (US)

(21) Appl. No.: 18/194,522

(22) Filed: Mar. 31, 2023

(51) Int. Cl. H05K 7/20

(52) U.S. Cl. CPC H05K 7/20836; H05K 7/20172; H05K 7/20209

(57) ABSTRACT

Methods and apparatus to manage noise in computing systems are disclosed. An example server includes a housing to at least partially contain components of the server, a transducer to output an indication of noise detected outside of the housing, machine readable instructions, and programmable circuitry to at least one of instantiate or execute the machine readable instructions to adjust the operation of the server based on the output of the transducer to reduce noise.

### FIELD OF THE DISCLOSURE

This disclosure relates generally to computing systems and, more particularly, to methods and apparatus to manage noise in computing systems.

### BACKGROUND

Computing systems may produce audible acoustic noise due to vibrations, fan systems, or other cooling systems of the computing systems. Many computing systems are located in or near public areas, workplaces, homes, etc. For example, some edge computing systems may be placed on telephone poles, street-side cabinets, etc.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack.

FIG. 5 is a block diagram of an example server in accordance with teachings of this disclosure.

FIGS. 6 and 7 illustrate example servers in which the teachings of this disclosure can be implemented.

FIGS. 8 and 9 illustrate example noise levels in an example territory.

FIG. 10 is a graphical illustration showing example heat dissipation as a function of fan speed and example noise levels as a function of fan speed.

FIG. 11 is a block diagram of another example server constructed in accordance with teachings of this disclosure.

FIG. 12 illustrates an example process flow in accordance with teachings of this disclosure.

FIG. 13 is a flowchart representative of example machine readable instructions and/or example operations that may be executed, instantiated, and/or performed by example programmable circuitry to implement the noise mitigation circuitry 522 of FIG. 5.

FIG. 14 is a block diagram of an example processing platform including programmable circuitry structured to execute, instantiate, and/or perform the example machine readable instructions and/or perform the example operations of FIG. 13 to implement the noise mitigation circuitry 522 of FIG. 5.

FIG. 15 is a block diagram of an example implementation of the programmable circuitry of FIG. 14.

FIG. 16 is a block diagram of another example implementation of the programmable circuitry of FIG. 14.

FIG. 17 is a block diagram of an example software/firmware/instructions distribution platform (e.g., one or more servers) to distribute software, instructions, and/or firmware (e.g., corresponding to the example machine readable instructions of FIG. 13) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Computing systems may use fans for cooling, which allow the systems to run at higher power and achieve increased performance. However, fans create acoustic noise. Users of such computing systems often find acoustic fan noise irritating, particularly when the system is running heavy workloads that may require increased operation of the fans. Aspects of acoustic noise that are problematic or irritating include the level (e.g., decibel level, volume, etc.) of the noise and the harshness (e.g., quality) of the noise. In some examples, data centers and/or servers located in cities or neighborhoods (e.g., edge computing nodes located in public or otherwise populated areas) may irritate pedestrians, animals, people in nearby homes, etc.

Edge computing is a developing paradigm where computing is performed at or closer to the “Edge” of a network, typically through the use of a compute platform (e.g., x86 or ARM compute hardware architecture) implemented at base stations, gateways, network routers, or other devices which are much closer to endpoint devices producing and consuming the data. Edge computing resources are located much closer to the endpoint (consumer and producer) data sources (e.g., autonomous vehicles, user equipment, business and industrial equipment, video capture devices, drones, smart cities and building devices, sensors and IoT devices, etc.) than “cloud” data center resources. Compute, memory, and storage resources which are offered at the edges (e.g., in an Edge cloud) may provide ultra-low latency response times for services and functions used by the endpoint data sources as well as reduce network backhaul traffic toward a cloud data center thus improving energy consumption and overall network usages among other benefits.

For example, Edge gateway servers may be equipped with pools of memory and storage resources to perform computation in real-time for low latency use-cases (e.g., autonomous driving or video surveillance) for connected client devices. Or as an example, base stations may be augmented with compute and acceleration resources to directly process service workloads for connected user equipment, without further communicating data via backhaul networks. Or as another example, central office network management hardware may be replaced with standardized compute hardware that performs virtualized network functions and offers compute resources for the execution of services and consumer functions for connected devices. Within Edge computing networks, there may be scenarios in which the compute resource will be “moved” to the data, as well as scenarios in which the data will be “moved” to the compute resource. Or as an example, base station compute, acceleration and network resources can provide services in order to scale to workload demands on an as needed basis by activating dormant capacity (subscription, capacity on demand) in order to manage corner cases, emergencies or to provide longevity for deployed resources over a significantly longer implemented lifecycle.

As disclosed herein, an example server dynamically (e.g., automatically) adjusts system configuration parameters (e.g., fan operations) to control system noise emitted from electronic components of the server. Examples disclosed herein control the noise characteristics of example servers for improved human perception. Further, examples disclosed herein mitigate noise of an example server while maintaining higher priority operations of the server. In some examples, disclosed systems can adjust the operations of component devices based on priority levels corresponding to the component devices. Examples disclosed herein enable example servers to control noise output based on noise levels of the environment. In some examples, disclosed systems utilize sensors to dynamically monitor a noise level of an example surrounding environment such that the example server can reduce noise levels to below that of the surrounding environment. Further, examples disclosed herein enable example servers to control and/or mitigate noise based on temperature levels (e.g., heat dissipation) associated with component devices of the server. For example, examples disclosed herein can reduce fan operations associated with component devices that may be generating more heat than other component devices.

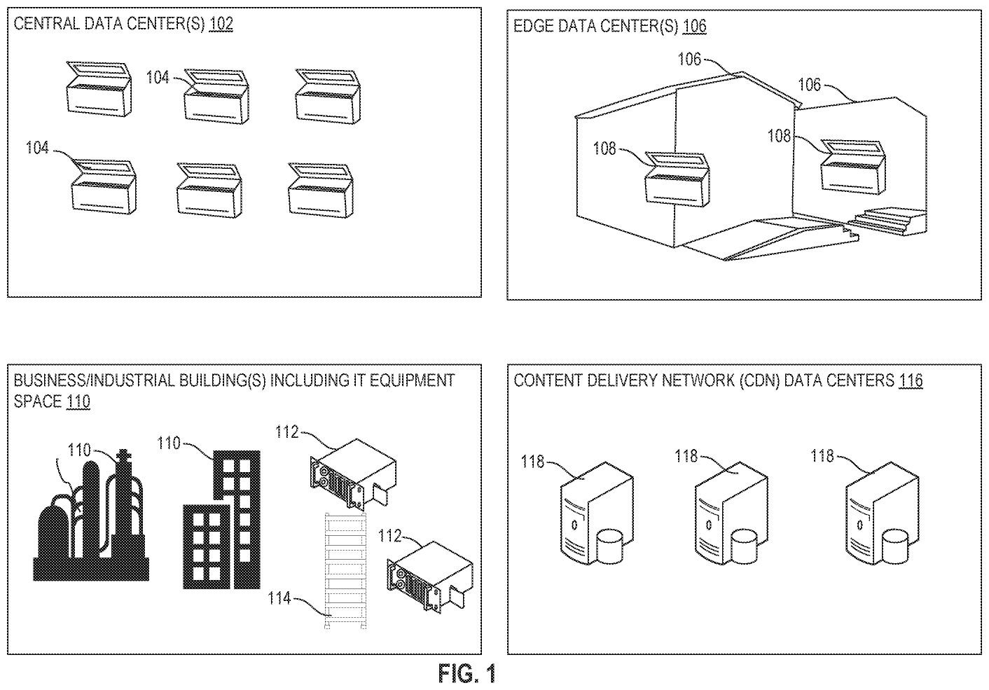

FIG. 1 illustrates one or more example environments in which teachings of this disclosure may be implemented. The example environments include one or more data centers. As used herein the term data center refers to any location at which one or multiple computing resources are located. Such computing resources may be any type of computing resources such as server(s), special purpose processing device(s), internet of things (IoT) device(s), edge computing device(s), rack(s) including one or more processing devices, cabinet(s) containing computing resource(s), etc.

The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. In some examples, such edge data centers may be located near a street, near a building, near a public park, or near any other area that may occasionally or frequently be populated with people. The edge data center(s) 106 include respective housings that store server(s), where the server(s) can be in communication with, for instance, the server(s) stored at the central data center(s) 102, client devices, and/or other compute devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of residence, business, and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premises server(s) of an edge computing network, where the on-premise server(s) are in communication with remote server(s) (e.g., the server(s) at the edge data center(s) 106) and/or other compute device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

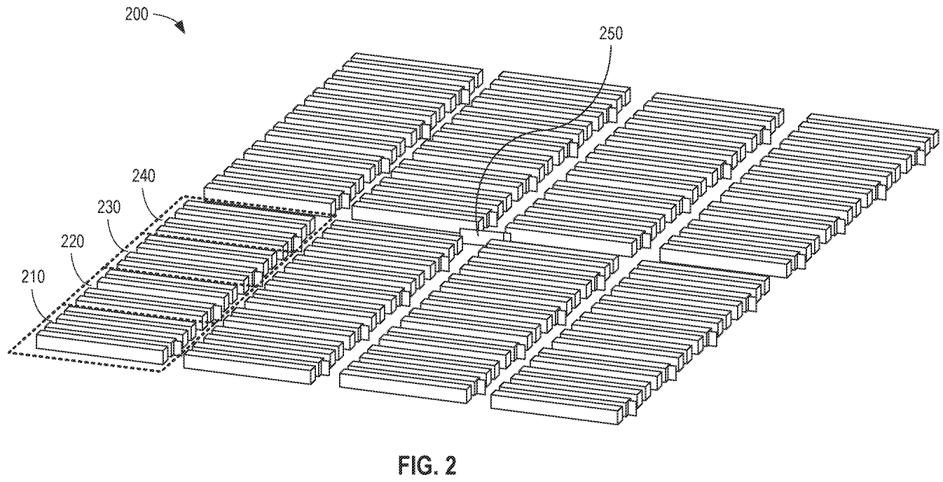

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

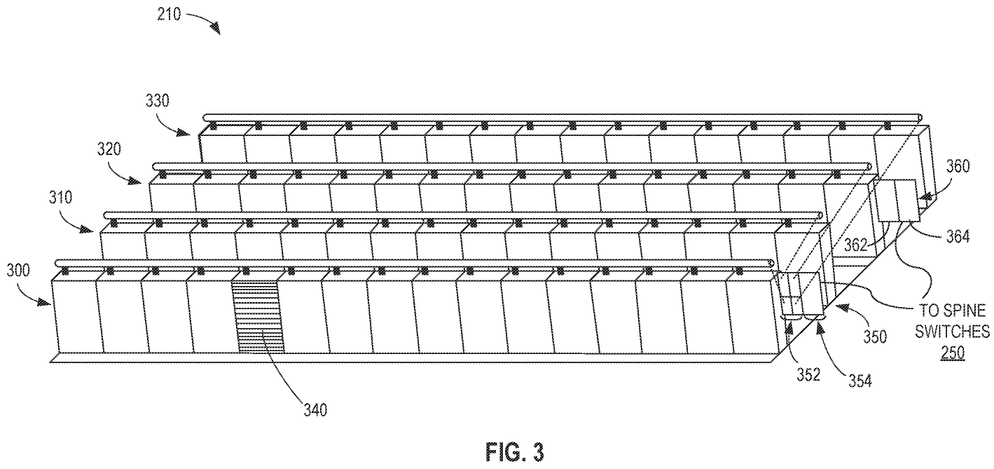

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

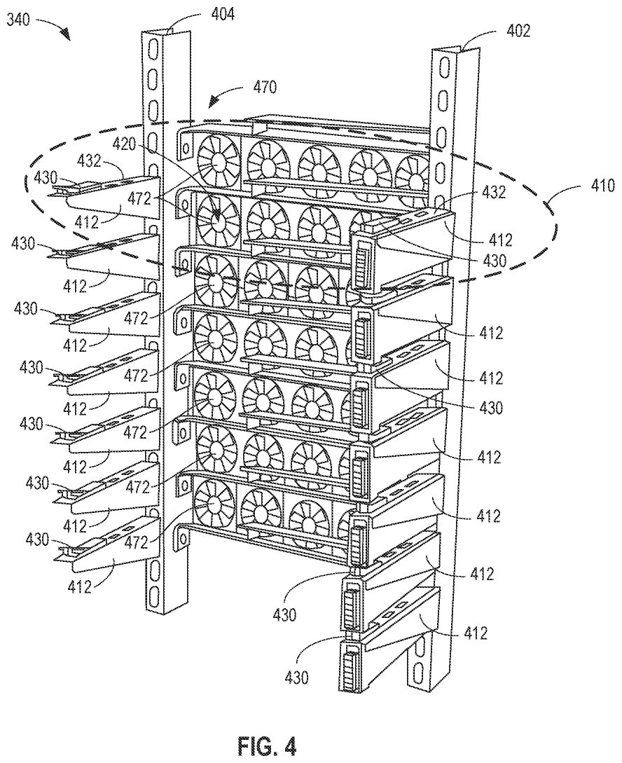

FIG. 4 illustrates an example rack 340 of a data center (e.g., one of the data centers 102, 106, 110, 116 of FIG. 1). As shown in the illustrated example, the rack 340 includes two elongated support posts 402, 404, which are arranged vertically. For example, the elongated support posts 402, 404 may extend upwardly from a floor of the data center when deployed. The rack 340 also includes one or more horizontal pairs 410 of elongated support arms 412 (identified in FIG. 4 via a dashed ellipse) configured to support a sled of the data center as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIG. 4, not every circuit board guide 430 may be referenced in each figure. In some examples, at least some of the sleds include a chassis and the racks 340 are suitably adapted to receive the chassis.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled as discussed above. In other examples, the rack 340 may include additional or fewer pairs 410 of elongated support arms 412 (i.e., additional or fewer sled slots 420).

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

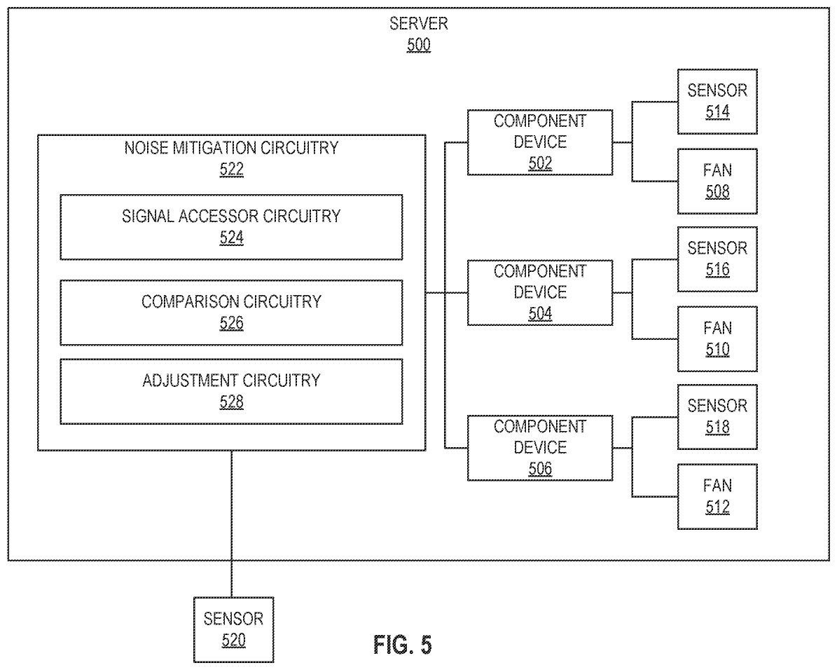

FIG. 5 is a block diagram of an example server 500 constructed in accordance with teachings of this disclosure to detect and/or control operation to mitigate noise. The example server 500 includes example component devices 502, 504, 506, example fans 508, 510, 512, example sensors 514, 516, 518, 520, and example noise mitigation circuitry 522. The example server 500 of FIG. 5 is implemented as an edge server. However, the server 500 can be implemented as any other type of computing system, such as a server computer, desktop computer, laptop computer, mobile device, etc. The example component devices 502, 504, 506 can include any device configured to transmit, receive, and/or otherwise manipulate electrical signals inside the example server 500. In some examples, the component devices 502, 504, 506 produce audible noise associated with electrical signals during operation. For example, the component devices 502, 504, 506 can include a voltage regulator that vibrates at a particular frequency and/or amplitude based on the voltage signal received by the voltage regulator. Though three component devices 502, 504, 506 are shown, in other examples, there may be a different number of component devices including, for example, two, four, etc.

The example fans 508, 510, 512 are configured to cool the example component devices 502, 504, 506. In the example of FIG. 5, the each of the fans 508, 510, 512 correspond to one of the component devices 502, 504, 506 respectively. However, the example fans 508, 510, 512 can be configured in any orientation with respect to the component devices 502, 504, 506. For example, one of the fans 508, 510, 512 can be configured to cool any two, three, etc. of the component devices 502, 504, 506. Further, although three fans 508, 510, 512 are shown, there may be a different number of fans including, for example, two, four, etc.

In some examples, the sensors 514, 516, 518, 520 can be any transducer device (e.g., microphone, etc.) configured to detect (e.g., monitor, track, etc.) effects such as pressure waves, vibrations, or other indications of noise, oscillation, vibration, etc. in and/or around the example server 500 and convert (e.g., output) the detected effects into an electrical signal and/or electrical quantity representative of the effects (e.g., values measured in decibels (dBs), dBA, etc.). In some examples, the sensors 514, 516, 518, 520 are physically coupled to the server 500 (e.g., built-in). In other examples, the sensors 514, 516, 518, 520 can include external devices that are electrically coupled to the server 500 via a wired or wireless connection. Additionally or alternatively, the example sensors 514, 516, 518, 520 can be any combination of transducer devices configured to measure (e.g., monitor) temperature, thermal, and/or heat dissipation metrics in the example server 500 and convert the metrics into an electrical signal and/or electrical quantity (e.g., Celsius (C)). Accordingly, the example sensors 514, 516, 518, 520 can include thermocouples that are electrically coupled to the server 500 and/or the component devices 502, 504, 506. In some examples, the sensors 514, 516, 518, 520 can output a thermal quantity referred to as junction-to-ambient (θJA). As used herein, junction-to-ambient denotes a thermal resistance measurement from an example device to the ambient air. In other words, θJA is a measurement of the ability of the example device to dissipate heat from a surface of the example device (e.g., junction) to the ambient air.

In the example of FIG. 5, the sensor 514 is configured to determine (e.g., detect) noise, temperature, θJA, etc., associated with at least one of the fan 508 or the component device 502. The example sensor 516 is configured to determine noise, temperature, θJA, etc., associated with at least one of the fan 510 or the component device 504. The example sensor 518 is configured to determine noise, temperature, θJA, etc., associated with at least one of the fan 512 or the component device 506. Further, the example server 500 may be communicatively coupled to the external sensor 520 configured to obtain data associated with an environment of the server 500. In other examples, the external sensor 520 obtains data indicating an external perception of the sound generated by the server 500. For example, the external sensor 520 can detect how loud the server 500 is outside of an example housing/cover of the server 500. In some examples, the server 500 can include example sensors at different positions within an example chassis that can determine a noise output (e.g., 3 dimensional (3D) noise output, wholistic noise output, etc.) of the server 500. The example noise mitigation circuitry 522 obtains sensor data (e.g., electrical signals, thermal metrics, noise data, θJA, etc.) from the sensors 514, 516, 518, 520 and analyzes the sensor data to monitor (e.g., adjust, reduce, etc.) operations associated with the server 500 and/or the component devices 502, 504, 506.

The example noise mitigation circuitry 522 includes one or more hardware and/or software components configured to obtain information from the sensors 514, 516, 518, 520, the fans 508, 510, 512 and/or the component devices 502, 504, 506. As shown in the example of FIG. 5, the noise mitigation circuitry 522 includes example signal accessor circuitry 524, comparison circuitry 526, and example adjustment circuitry 528. The example noise mitigation circuitry 522 of FIG. 5 may be instantiated (e.g., creating an instance of, bring into being for any length of time, materialize, implement, etc.) by programmable circuitry such as a Central Processor Unit (CPU) executing first instructions. Additionally or alternatively, the noise mitigation circuitry 522 of FIG. 5 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 5 may, thus, be instantiated at the same or different times. Some or all of the circuitry of FIG. 5 may be instantiated, for example, in one or more threads executing concurrently on hardware and/or in series on hardware. Moreover, in some examples, some or all of the circuitry of FIG. 5 may be implemented by microprocessor circuitry executing instructions and/or FPGA circuitry performing operations to implement one or more virtual machines and/or containers.

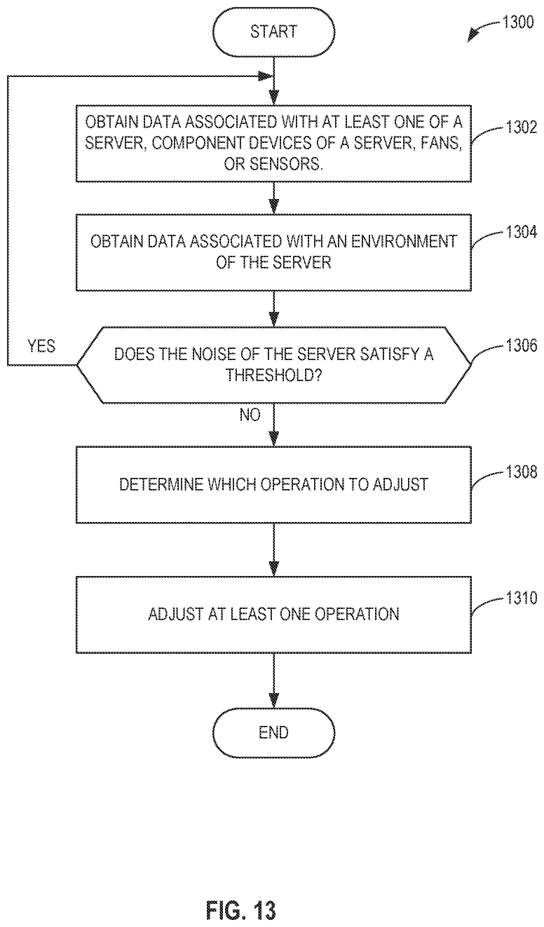

The example signal accessor circuitry 524 obtains (e.g., accesses) sensor data from at least one of the sensors 514, 516, 518, 520 (e.g., transducers). In some examples, the signal accessor circuitry 524 obtains sensor data (e.g., electrical signals) associated with operation(s) of the server 500, operations of the component devices 502, 504, 506 and/or operations of the fans 508, 510, 512. For example, the signal accessor circuitry 524 can obtain data indicative of sound (e.g., noise levels, dB levels, etc.) associated with at least one of the component devices 502, 504, 506. Additionally or alternatively, the example signal accessor circuitry 524 can obtain data indicative of sound associated with at least one of the fans 508, 510, 512. In some examples, the signal accessor circuitry 524 can obtain data indicative of temperature metrics (e.g., heat dissipation, thermal resistance, thermal airflow, θJAs, etc.) associated with at least one of the component devices 502, 504, 506. Additionally or alternatively, the example signal accessor circuitry 524 can obtain data indicative of temperature metrics associated with at least one of the fans 508, 510, 512. In some examples, the signal accessor circuitry 524 is instantiated by programmable circuitry executing signal accessing instructions and/or configured to perform operations such as those represented by the flowchart of FIG. 13.

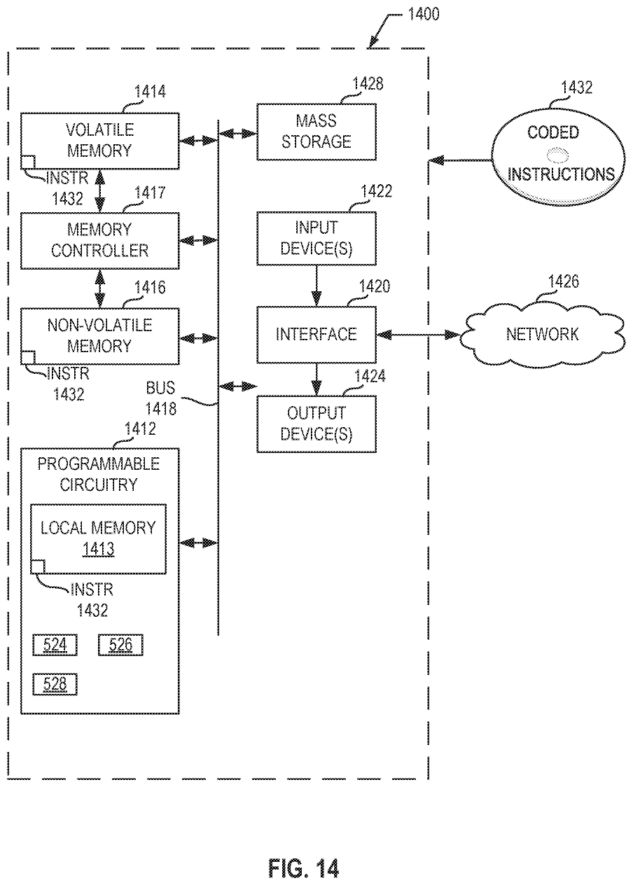

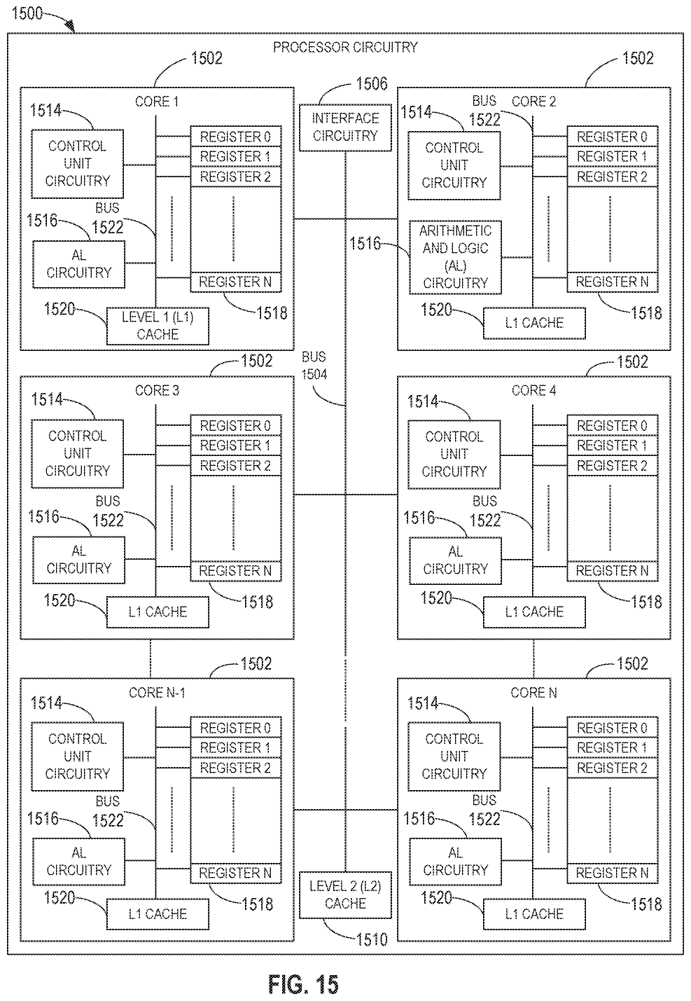

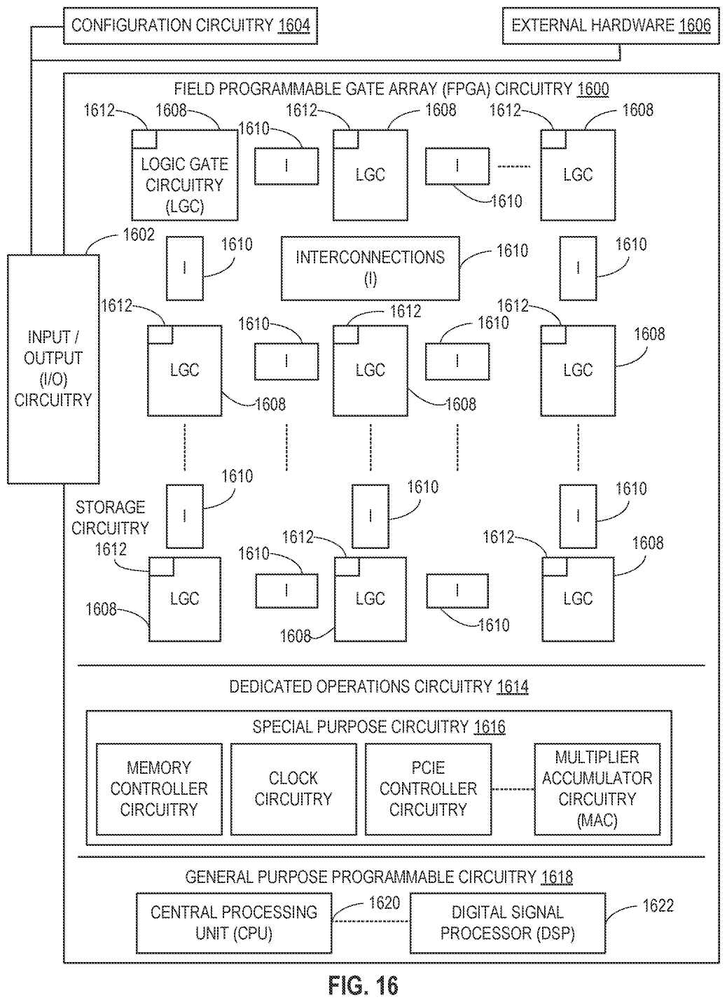

In some examples, the noise mitigation circuitry 522 includes means for accessing a signal. For example, the means for accessing may be implemented by signal accessor circuitry 524. In some examples, the signal accessor circuitry 524 may be instantiated by programmable circuitry such as the example programmable circuitry 1412 of FIG. 14. For instance, the signal accessor circuitry 524 may be instantiated by the example microprocessor 1500 of FIG. 15 executing machine executable instructions such as those implemented by at least blocks 1302 and 1304 of FIG. 13. In some examples, signal accessor circuitry 524 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the signal accessor circuitry 524 may be instantiated by any other combination of hardware, software, and/or firmware. For example, the signal accessor circuitry 524 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example comparison circuitry 526 compares operations of the component devices 502, 504, 506. For example, the comparison circuitry 526 compares an operation of the component device 502 to an operation of the component device 504. In some examples, the operation of the component device 502 may be a higher priority than the operation of the component device 504. In some examples, the comparison circuitry 526 assigns priority levels to the component devices 502, 504, 506. For example, the comparison circuitry 526 can assign a first priority level (e.g., C4) to the component device 502 and a second priority level (e.g., C5) to the component device 504. Accordingly, the comparison circuitry 526 can determine that the second priority level is higher than the first priority level and, thus, that the component device 504 should be prioritized.

In some examples, the comparison circuitry 526 compares signal outputs (e.g., electrical signals, dB level, thermal metrics, θJAs, etc.) of the sensors 514, 516, 518, 520. For example, the comparison circuitry 526 can compare a first signal output (e.g., 60 dBs, 0.36 θJA, etc.) of the sensor 514 to a second signal output (e.g., 30 dBs, 0.25 θJA) of the sensor 516. Accordingly, the comparison circuitry 526 can determine that the first signal output is greater than the second signal output and, thus, that the associated component device 502 is louder and/or generating more heat than the component device 504. In some examples, the comparison circuitry 526 compares operations of the fans 508, 510, 512. For example, the comparison circuitry 526 can compare an operation of the fan 508 (e.g., 3200 revolutions per minute (RPM)) to an operation of the fan 510 (e.g., 2000 RPM). Further, the comparison circuitry 526 can determine that the operation of the fan 508 is greater than the operation of the fan 510 (e.g., 3200 RPM>2000 RPM). In such examples, the higher operation of the fan 508 can indicate that the associated component device 502 is generating more heat (e.g., exceeding a temperature threshold) than the component device 504 and, thus, may need cooling. In some examples, the comparison circuitry 526 is instantiated by programmable circuitry executing comparing instructions and/or configured to perform operations such as those represented by the flowchart of FIG. 13.

In some examples, the noise mitigation circuitry 522 includes means for comparing operations of the component devices 502, 504, 506 and/or the fans 508, 510, 512. For example, the means for comparing may be implemented by comparison circuitry 526. In some examples, the comparison circuitry 526 may be instantiated by programmable circuitry such as the example programmable circuitry 1412 of FIG. 14. For instance, the comparison circuitry 526 may be instantiated by the example microprocessor 1500 of FIG. 15 executing machine executable instructions such as those implemented by at least blocks 1306 and 1308 of FIG. 13. In some examples, comparison circuitry 526 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the comparison circuitry 526 may be instantiated by any other combination of hardware, software, and/or firmware. For example, the comparison circuitry 526 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example adjustment circuitry 528 adjusts (e.g., changes, alters, reduces, etc.) the operation of the server 500 based on the output of at least one of the sensors 514, 516, 518, 520. In some examples, the adjustment circuitry 528 adjusts the operation of at least one of the component devices 502, 504, 506 based on the output of at least one of the sensors 514, 516, 518, 520. In some examples, the adjustment circuitry 528 adjusts the operation of at least one of the component devices 502, 504, 506 based on priority levels associated with the component devices 502, 504, 506. For example, the adjustment circuitry 528 can adjust the operation of the component device 502 based on the component device 502 having a lower priority than the component device 504 and/or the component device 506. In some examples, the adjustment circuitry 528 can adjust the operation of at least one of the component devices 502, 504, 506 piecewise (e.g., in parts) based on a time of day, a priority level of the at least one of the component devices 502, 504, 506, a thermal resistance measurement of the at least one of the component devices 502, 504, 506, an external input (e.g., a user/operator input), etc. For example, the adjustment circuitry 528 can adjust the operation of the component device 502 and/or the fan 508 to a first operational level (e.g., 70% power) at a first time (e.g., in the morning, at 4:00 PM, etc.) and to a second operational level (e.g., 30% power) at a second time (e.g., at 12 noon). In some examples the adjustment circuitry 528 adjusts the operations of the component devices 502, 504, 506 based on thermal resistance metrics associated with the component devices 502, 504, 506. For example, the adjustment circuitry 528 can adjust the operation of the component device 504 based on the component device 504 generating more heat (e.g., hotter) than the component device 502 and/or the component device 506. In some examples, the adjustment circuitry 528 adjusts a noise output of the server 500 by adjusting the operations of the component devices 502, 504, 506. In other examples, the adjustment circuitry 528 adjusts a noise output of the server 500 by adjusting the operations of the fans 508, 510, 512. In some examples, the adjustment circuitry 528 is instantiated by programmable circuitry executing adjusting instructions and/or configured to perform operations such as those represented by the flowchart of FIG. 13.

In some examples, the noise mitigation circuitry 522 includes means for adjusting an operation of a server, a component device, a fan, etc. For example, the means for adjusting may be implemented by adjustment circuitry 528. In some examples, the adjustment circuitry 528 may be instantiated by programmable circuitry such as the example programmable circuitry 1412 of FIG. 14. For instance, the adjustment circuitry 528 may be instantiated by the example microprocessor 1500 of FIG. 15 executing machine executable instructions such as those implemented by at least block 1310 of FIG. 13. In some examples, adjustment circuitry 528 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the adjustment circuitry 528 may be instantiated by any other combination of hardware, software, and/or firmware. For example, the adjustment circuitry 528 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

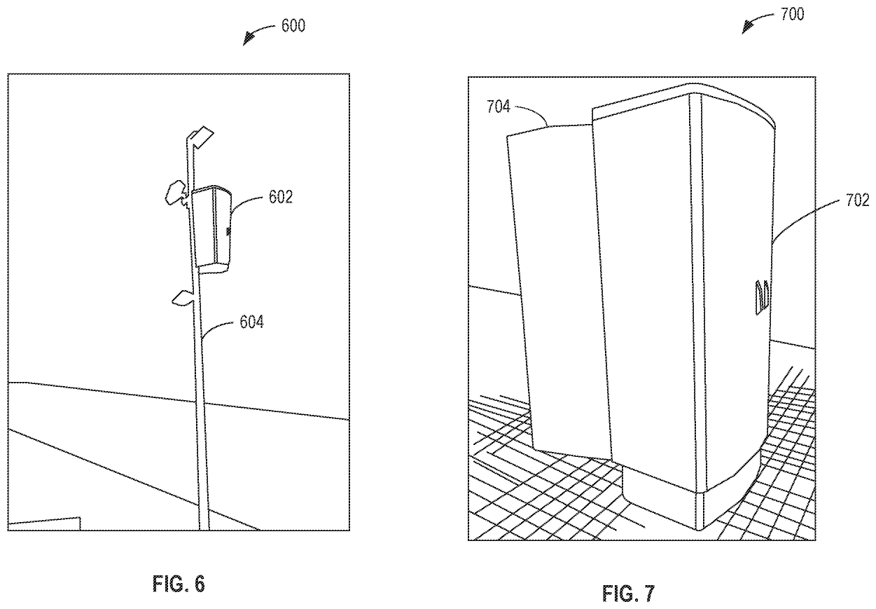

FIGS. 6 and 7 illustrate example servers 600, 700 in which the teachings of this disclosure can be implemented. In FIG. 6, the example server 600 is enclosed by an example housing 602. The example server 600 is positioned on an example lamp post (e.g., light post) 604. Turning to FIG. 7, the example server 700 is enclosed by an example housing 702 and includes an example door 704. The example servers 600, 700 may be positioned (e.g., located) on neighborhood streets, city streets, intersections, etc. In other examples, the servers 600, 700 may be located in parks, town squares, etc. Accordingly, the example housings 602, 702 can protect (e.g., cover) the servers 600, 700 from rain, snow, etc. Additionally or alternatively, the example housings 602, 702 can protect (e.g., shield) pedestrians from high voltage equipment contained within the example servers 600, 700. In some examples, the servers 600, 700 may be referred to as “street cabinets.” In some examples, the example servers 600, 700 are located in office spaces. The example servers 600, 700 can function to bring compute resources, such as WI-FI, closer to data sources (e.g., homes, offices, mobile devices, etc.).

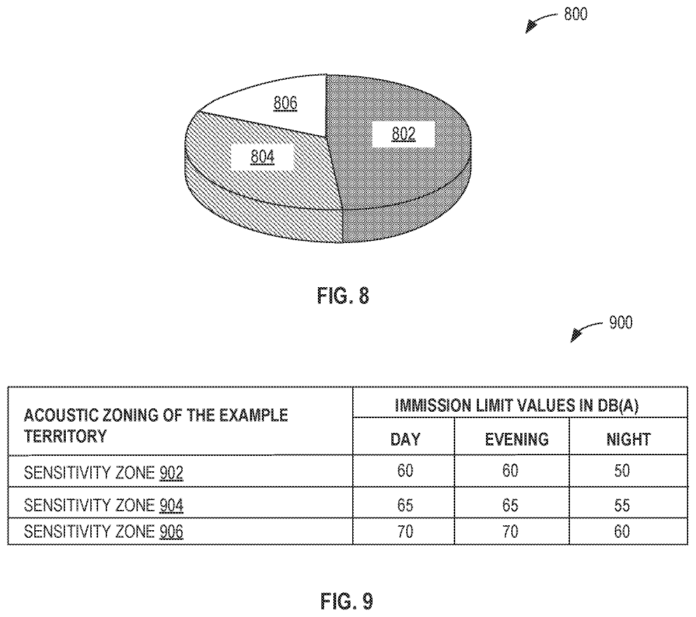

FIGS. 8 and 9 illustrate example noise levels in an example territory (e.g., Chicago, Milwaukee, etc.). In FIG. 8, an example pie graph 800 illustrates noise sensitivity zones by street in the example territory. In FIG. 9, an example table 900 details the example noise (e.g., acoustic) sensitivity zones 902, 904, 906 according to a time of day. For example, Chicago may have a first percentage 802 (e.g., 48.27%) of streets that correspond to a first noise sensitivity zone 902 (e.g., high sensitivity), a second percentage 804 (e.g., 36.61%) of streets that correspond to a second noise sensitivity zone 904 (e.g., moderate sensitivity), and a third percentage 806 (e.g., 19.12%) of streets that correspond to a third noise sensitivity zone 906 (e.g., low sensitivity). In some examples, a noise sensitivity zone may depend on residential areas of Chicago. For example, residential streets in Chicago may be assigned to the high sensitivity zone and urban (e.g., financial district) streets in Chicago may be assigned to the low sensitivity zone. In some examples, the zones 902, 904, 906 may be determined by residents, elected officials, law enforcement officials, etc.

In FIG. 9, the example data table 900 indicates that the example sensitivity zones 902, 904, 906 can include noise limits (e.g., noise thresholds, dBA thresholds, etc.) depending on the time of day. In some examples, the noise thresholds limit noise from music, concerts, homes, street cabinets, air conditioners, construction equipment, etc., to preserve the quality of life for neighbors, pedestrians, elderly, etc. According to the example table 900, an example server (e.g., the server 500, the server 600, the server 700, etc.) located in the zone 902 may not exceed a noise output of 60 dBA during the day (e.g., 7:00 AM to 9:00 PM). In the zone 902, an example server may not exceed a noise output of 60 dBA during the evening (e.g., 9:00 PM to 11:00 PM). Further, an example server located in the zone 902 may not exceed a noise output of 50 dBA during the night (e.g., 11:00 PM to 7:00 AM). An example server located in the zone 904 may not exceed a noise output of 65 dBA during the day, 65 dBA during the evening, and 55 dBA during the night. Further, an example server located in the zone 816 may not exceed a noise output of 70 dBA during the day, 70 dBA during the evening, and 60 dBA during the night.

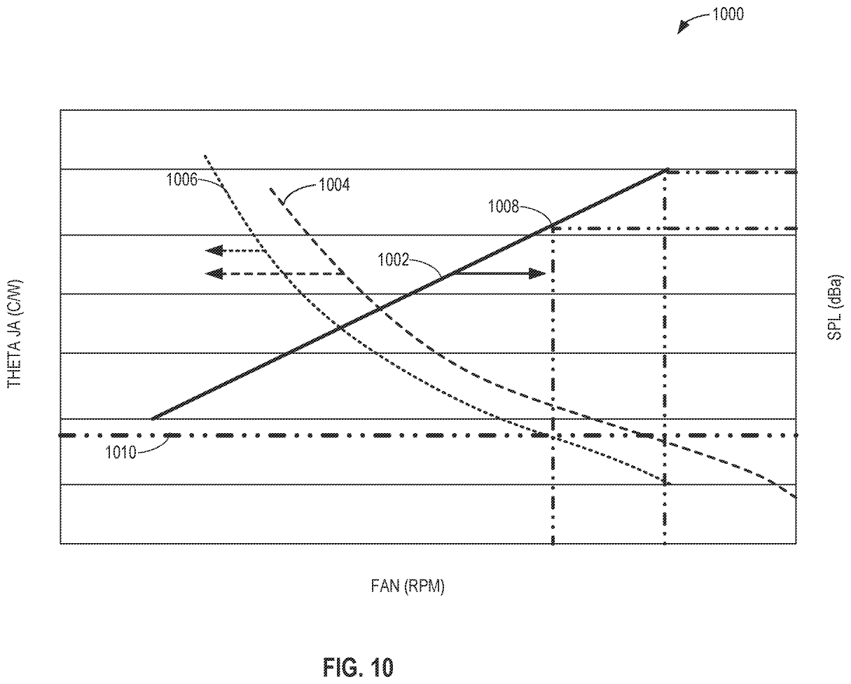

FIG. 10 is a graphical illustration 1000 includes example plots 1002, 1004, and 1006. The example plot 1002 represents the noise output (e.g., sound pressure level (SPL) in dBA) of an example fan as the thermal resistance (e.g., θJAs) of an example server and/or example component devices increases and as fan speed (e.g., RPM) increases. For example, point 1008 represents that the example fan 508 is operating at 3200 RPM to cool the component device 502. Further, point 1008 indicates that the example sensor 514 detects a thermal resistance of 0.36 θJAs (e.g., Celsius per Watt (C/W)) associated with the component device 502. The example plot 1002 also indicates that the sensor 514 detects a noise output of 75 dBA associated with the example fan 508. In some examples, line 1010 represents an example maximum overall resistance of the example server 500.

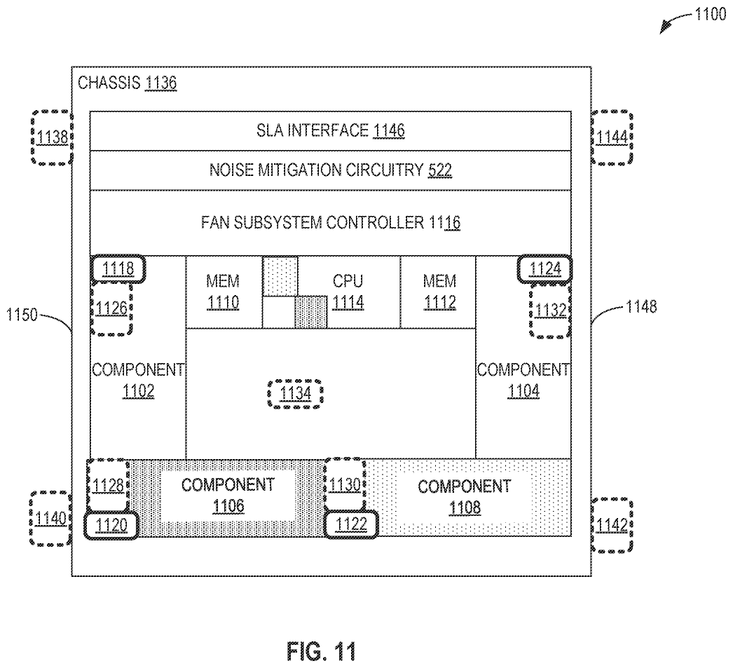

FIG. 11 is a block diagram of an example server 1100 constructed in accordance with teachings of this disclosure. The example server 1100 includes example component devices 1102, 1104, 1106, 1108, example memory stores 1110, 1112, an example central processing unit (CPU) 1114, an example fan subsystem controller 1116, example fans 1118, 1120, 1122, 1124, example sensors 1126, 1128, 1130, 1132, 1134, an example chassis 1136, example external sensors 1138, 1140, 1142, 1144, an example Service Level Agreement (SLA) Interface 1146, and the example noise mitigation circuitry 522.

The example server 1100 includes the chassis 1136 for structure, support, containment, etc. For example, the external sensors 1138, 1140, 1142, 1144 can be mounted on external surfaces of the chassis 1136 to obtain data indicating an external perception of the sound generated by the server 1100 and/or a temperature (e.g., weather) associated with an environment surrounding the server 1100. In such examples, the SLA Interface 1146 can communicatively couple the external sensors 1138, 1140, 1142, 1144 to the noise mitigation circuitry 522. Thus, the noise mitigation circuitry 522 can analyze the data transmitted from the SLA Interface 1146 to monitor operations associated with the server 1100, surroundings of the server 1100, the component devices 1102, 1104, 1106, 1108, and/or the fans 1118, 1120, 1122, 1124.

In FIG. 11, the example sensor 1126 is configured to determine noise, temperature, θJA, etc. associated with at least one of the fan 1118 or the component device 1102. The example sensor 1128 is configured to determine noise, temperature, θJA, etc. associated with at least one of the fan 1120 or the component device 1106. The example sensor 1130 is configured to determine noise, temperature, θJA, etc. associated with at least one of the fan 1122 or the component device 1108. Further, the example sensor 1132 is configured to determine noise, temperature, θJA, etc. associated with at least one of the fan 1124 or the component device 1104. Additionally or alternatively, the example sensor 1134 can be configured to determine noise, temperature, θJA, etc. associated with any component (e.g., the CPU 1114, the component devices 1102, 1104, 1106, 1108, the fans 1118, 1120, 1122, 1124, etc.) in the server 1100. The example noise mitigation circuitry 522 obtains sensor data from the sensors 1126, 1128, 1130, 1132, 1134 and analyzes the sensor data to monitor operations associated with the server 1100, the component devices 1102, 1104, 1106, 1108, and/or the fans 1118, 1120, 1122, 1124. In some examples, at least one of the memory stores 1110, 1112 can store the sensor data and/or data indicating the operations of the server 1100, the component devices 1102, 1104, 1106, 1108, the fans 1118, 1120, 1122, 1124, etc.

The example server 1100 includes the fan subsystem controller 1116 to adjust (e.g., control) operations of the fans 1118, 1120, 1122, 1124. The example fan subsystem controller 1116 may be operatively and/or communicatively coupled to the noise mitigation circuitry 522 and/or the adjustment circuitry 528. In some examples, the fan subsystem controller 1116 is communicatively coupled to the SLA Interface 1146 via the noise mitigation circuitry 522.

In the example of FIG. 11, SLA Interface 1146 and/or the noise mitigation circuitry 522 can determine the workloads, priority levels, operations, criticalities, etc., associated with the component devices 1102, 1104, 1106, 1108. In some examples, the component devices 1102, 1104, 1106, 1108 may have different levels of priority in the server 1100 based on the functions provided by the component devices 1102, 1104, 1106, 1108. For example, the comparison circuitry 526 can assign a first priority level (e.g., C4) to the component device 1106 and a second priority level (e.g., C5) to the component device 1108. In other examples, the operation (e.g., workload, function, frequency, etc.) of the component device 1108 may be a higher priority than the operation of the component device 1106. Accordingly, the comparison circuitry 526 can determine that the second priority level is higher than the first priority level and, for example, that the component device 1108 should be prioritized. Additionally or alternatively, the example comparison circuitry 526 can determine that the operation of the component device 1106 can be adjusted based on the second priority level being greater than the first priority level.

In some examples, the noise mitigation circuitry 522 and/or the adjustment circuitry 528 can adjust operations of the component devices 1102, 1104, 1106, 1108 based on priority levels associated with the component devices 1102, 1104, 1106, 1108. For example, if the comparison circuitry 526 determines that the component device 1108 has the highest priority level in the server 1100, then the adjustment circuitry 528 can adjust the operations of the component devices 1102, 1104, 1106. Additionally or alternatively, the example adjustment circuitry 528 can adjust operations of the fans 1118, 1120, 1124 based on the component device 1108 having the highest priority level. In other words, the high priority level associated with the component device 1108 can indicate the operations of the component device 1108 or the cooling of the component device 1108 should not be reduced because such a reduction may impede performance of the server 1100. Accordingly, the component device 1108 may be the loudest of the devices 1102, 1104, 1106, 1108, but the noise mitigation circuitry 522 may reduce operations of at least one of the component devices 1102, 1104, 1106 instead of the component device 1108. As such, the noise mitigation circuitry 522 can reduce noise levels associated with the server 1100 without hindering performance of the server 1100 and/or critical/high priority components of the server 1100 (e.g., the component device 1108).

In some examples, the noise mitigation circuitry 522 and/or the adjustment circuitry 528 can adjust operations of the component devices 1102, 1104, 1106, 1108 and/or the fans 1118, 1120, 1122, 1124 based on sensor data obtained by the external sensors 1138, 1140, 1142, 1144. For example, at least one of the external sensors 1138, 1140, 1142, 1144 can determine a noise level (e.g., a dB level, a dB metric, etc.) associated with the surroundings of the server 1100. In some examples, the noise mitigation circuitry 522 can determine that the noise level obtained by the at least one of the external sensors 1138, 1140, 1142, 1144 is a threshold noise level.

In some examples, at least one of the external sensors 1138, 1140, 1142, 1144 can detect a first dBA level (e.g., 75 dBA) associated with an environment (e.g., a concert, a construction zone, a busy street, surroundings, etc.) of the server 1100. The example external sensors 1138, 1140, 1142, 1144 are communicatively coupled to the SLA Interface 1146 and/or the noise mitigation circuitry 522 such that the noise mitigation circuitry 522 can obtain the first dBA level associated with the surroundings. As such, the example comparison circuitry 526 can compare the first dBA level associated with the surroundings to a second dBA level (e.g., 85 dBA) associated with at least one of the component devices 1102, 1104, 1106, 1108, the fans 1118, 1120, 1122, 1124, etc.

In response to the example comparison circuitry 526 determining that the second dBA level is greater than the first dBA level (e.g., 85 dBA>75 dBA), the example adjustment circuitry 528 can adjust operations of at least one of the component devices 1102, 1104, 1106, 1108, the fans 1118, 1120, 1122, 1124, etc. In some examples, such as based on an example noise sensitivity zone (e.g., zones 902, 904, 906), the operations of the at least one of the component devices 1102, 1104, 1106, 1108, the fans 1118, 1120, 1122, 1124, etc., may be reduced such that the second dBA level (e.g., noise inside the server 1100) is less than or equal to the first dBA level (e.g., noise outside the server 1100). As such, the example adjustment circuitry 528 can reduce (e.g., dampen) operations of the at least one of the component devices 1102, 1104, 1106, 1108, the fans 1118, 1120, 1122, 1124, etc., in order to satisfy an example noise threshold.

In some examples, the noise mitigation circuitry 522 and/or the adjustment circuitry 528 can adjust operations of the component devices 1102, 1104, 1106, 1108 and/or the fans 1118, 1120, 1122, 1124 based on example walls 1148, 1150 of the chassis 1136. For example, the wall 1148 may be more insulative (e.g., include more insulation material, thicker, etc.) than the wall 1150. The example noise mitigation circuitry 522 can detect that the component device 1104 and the component device 1108 are closer to the wall 1148 than to the wall 1150. Accordingly, noise associated with the component devices 1104, 1108 may be better insulated (e.g., mitigated, dampened) than the component devices 1102, 1106 based on the proximity of the component devices 1104, 1108 to the wall 1148.

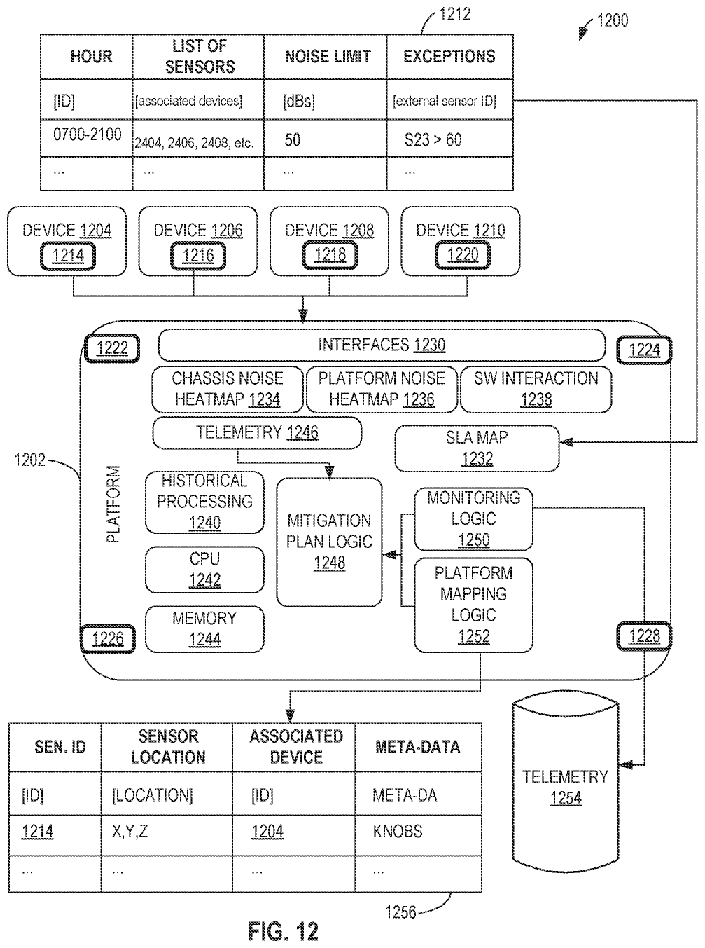

FIG. 12 illustrates an example process flow 1200 in accordance with teachings of this disclosure. The example process flow 1200 includes an example platform 1202 that can be implemented as an example server (e.g., the servers 500, 600, 700, 1100, etc.), for example. The example platform 1202 can be communicatively coupled to example devices 1204, 1206, 1208, 1210. In FIG. 12, example data table 1212 provides inputs to the platform 1202. For example, the data table 1212 includes noise limits listed (e.g., organized) by example time interval (e.g., by the hour, during the daytime, during the evening, etc.) and identifies at least one example sensors 1214, 1216, 1218, 1220, 1222, 1224, 1226, 1228 included in the process flow 1200. The example data table 1212 further includes information (e.g., dB level, dB metric, etc.) associated with (e.g., gathered by) sensors external to the platform 1202. In some examples, the external sensors can detect noise associated with an environment of the platform 1202. In some examples, the external sensors can determine (e.g., define) a noise threshold for the devices 1204, 1206, 1208, 1210 and/or the platform 1202. The example data table 1212 can include exception rules determined by the list of external sensors and an example Boolean equation. For example, if the external noise sensor (e.g., outside the platform 1202, outside the server, etc.) detects an external noise at a dB level (e.g., 65 dB), then the platform noise output can be a percentage (e.g., 80%) of that dB level (e.g., 0.8*65=52 dB).

The example sensors 1214, 1216, 1218, 1220 detect noise, temperature, θJA, etc. associated with each of the example devices 1204, 1206, 1208, 1210. In some examples, the platform 1202 includes example sensors 1222, 1224, 1226, 1228 distributed throughout the platform 1202. The example platform 1202 includes example interfaces 2430 to access and/or obtain data from the sensors 1214, 1216, 1218, 1220, 1222, 1224, 1226, 1228, the devices 1204, 1206, 1208, 1210, etc. In some examples, the platform 1202 includes an example SLA Map 1232 that can obtain information corresponding to thermal thresholds (e.g., heat limit, temperature maximum, etc.) detected by the sensors 1222, 1224, 1226, 1228. In some examples, the thermal thresholds for the sensors 1222, 1224, 1226, 1228 can be at least one value. In some examples, the SLA Map 1232 can determine the noise output (e.g., noise output to satisfy SLA) for each of the sensors 1222, 1224, 1226, 1228 included in the platform 1202.

In some examples, the platform 1202 and/or an application program interface (API) can determine that at least one of the devices 1204, 1206, 1208, 1210 has exceeded an example noise threshold and/or is nearing (e.g., approaching) an example noise threshold. For example, the platform 1202 can determine that the noise output associated with the devices 1204, 1206, 1208, 1210 and/or the platform 1202 is within a percentage of the noise threshold. For example, if the noise threshold is 65 dBA, then the example platform 1202 can determine that an example platform noise output of 45.5 dBA is within 30% of the noise threshold (e.g., 65−(65*0.3)=45.5 dBA), an example platform noise output of 32.5 dBA is within 50% of the noise threshold (e.g., 65−(65*0.5)=32.5 dBA), an example platform noise output of 6.5 dBA is within 90% of the noise threshold (e.g., 65−(65*0.9)=6.5 dBA), etc. As such, the example platform 1202 can adjust the noise output associated with the devices 1204, 1206, 1208, 1210 and/or the platform 1202 before the platform noise output reaches the example noise threshold.

The example platform 1202 includes an example chassis noise heatmap 1234, an example platform noise heatmap 2436, and example software (SW) interaction logic 1238. The example chassis noise heatmap 1234 and/or the example platform noise heatmap 1236 can include (e.g., indicate) the amount of noise captured by each of the sensors 1214, 1216, 1218, 1220, 1222, 1224, 1226, 1228. In some examples, this is referred to as “passive monitoring”. In some examples, the platform 1202 can also notify the example interfaces 1230 and/or the example devices 1204, 1206, 1208, 1210 when an example noise threshold has been exceeded. In some examples, the SW interaction logic 1238 can generate notifications (e.g., signals, interrupts, alarms, etc.) directed to the interfaces 2430 and/or the platform 1202 when the noise output is within a percentage (e.g., 30%, 50%, 90%, etc.).

In FIG. 12, the example platform 1202 includes example historical processing 1240, an example CPU 1242, example memory 1244, example telemetry 1246, example mitigation plan logic 1248, example monitoring logic 1250, and example platform mapping logic 1252. In some examples, the monitoring logic 1250 can provide noise and/or or thermal telemetry to an example telemetry database 1254 (e.g., storage, media, etc.). Further, the monitoring logic 1250 can provide example telemetry to an example memory address that can be monitored via an instruction (e.g., MWAIT). In some examples, the monitoring logic 1250 can obtain (e.g., collect) the telemetry (e.g., noise, thermal, usage, etc.) over time (e.g., periodically) from the sensors 1214, 1216, 1218, 1220, 1222, 1224, 1226, 1228, the devices 1204, 1206, 1208, 1210, and/or the platform 1202.

In some examples, the platform 1202 can adjust operations of fans (e.g., an example cooling system) to adjust the noise output of the platform 1202. For example, an example API and/or the SW interaction logic 1238 can identify whether the operations of the fans should be increased or decreased (e.g., throttled). In some examples, the operations of the fans may be decreased in response to an external output (e.g., request) and/or a determination that the noise output of the platform 1202 has exceeded a noise threshold. In some examples, the operations of the fans may be adjusted temporally (e.g., in different phases).

In some examples, the platform mapping logic 1252 can determine (e.g., plan) noise mitigation for the platform 1202. For example, the platform mapping logic 1252 can identify high priority functions of the devices 1204, 1206, 1208, 1210 and/or any other component of the platform 1202 and adjust operations based on the priorities. In some examples, the platform mapping logic 1252 can determine which of the devices 1204, 1206, 1208, 1210 can better mitigate noise output (e.g., via insulation, via cooling, etc.) and adjust operations based on device characteristics. In some examples, the platform mapping logic 1252 and/or the example API can access example key performance indicators (KPIs) associated with the devices 1204, 1206, 1208, 1210. In such examples, the KPIs can indicate behavior, performance, function, processes, applications, etc., of the example devices 1204, 1206, 1208, 1210 within the platform 1202. As such, the example platform 1202 can adjust operations of the devices 1204, 1206, 1208, 1210 based on KPIs. In some examples, the platform mapping logic 1252 can output example data table 1256. The example data table 1256 indicates a sensor identification (ID) for at least one the sensors 1214, 1216, 1218, 1220, 1222, 1224, 1226, 1228, a location of the at least one of the sensors 1214, 1216, 1218, 1220, 1222, 1224, 1226, 1228 within the platform 1202, a device (e.g., at least one of the devices 1204, 1206, 1208, 1210) associated with the at least one of the sensors 1214, 1216, 1218, 1220, 1222, 1224, 1226, 1228, and metadata.

While an example manner of implementing the noise mitigation circuitry 522 is illustrated in FIG. 5, one or more of the elements, processes, and/or devices illustrated in FIG. 5 may be combined, divided, re-arranged, omitted, eliminated, and/or implemented in any other way. Further, the example signal accessor circuitry 524, the example comparison circuitry 526, the example adjustment circuitry 528 and/or, more generally, the example noise mitigation circuitry 522 of FIG. 5, may be implemented by hardware alone or by hardware in combination with software and/or firmware. Thus, for example, any of the example signal accessor circuitry 524, the example comparison circuitry 526, the example adjustment circuitry 528 and/or, more generally, the example noise mitigation circuitry 522, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example noise mitigation circuitry 522 of FIG. 5 may include one or more elements, processes, and/or devices in addition to, or instead of, those illustrated in FIG. 5, and/or may include more than one of any or all of the illustrated elements, processes and devices.

A flowchart representative of example machine readable instructions, which may be executed by programmable circuitry to implement and/or instantiate the noise mitigation circuitry 522 of FIG. 5 and/or representative of example operations which may be performed by programmable circuitry to implement and/or instantiate the noise mitigation circuitry 522 of FIG. 5, are shown in FIG. 13. The machine readable instructions may be one or more executable programs or portion(s) of one or more executable programs for execution by programmable circuitry such as the programmable circuitry 1412 shown in the example processor platform 1400 discussed below in connection with FIG. 14 and/or may be one or more function(s) or portion(s) of functions to be performed by the example programmable circuitry (e.g., an FPGA) discussed below in connection with FIGS. 15 and/or 16. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 13, many other methods of implementing the example noise mitigation circuitry 522 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C #, Perl, Python, JavaScript, HyperText Markup Language (HTML), Structured Query Language (SQL), Swift, etc.

As mentioned above, the example operations of FIG. 13 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 13 is a flowchart representative of example machine readable instructions and/or example operations 1300 that may be executed, instantiated, and/or performed by programmable circuitry to manage noise in an example server. The machine readable instructions and/or the operations 1300 of FIG. 13 begin at block 1302, at which the signal accessor circuitry 524 obtains data associated with at least one of the server 500, the component devices 502, 504, 506, the fans 508, 510, 512, or the sensors 514, 516, 518. For example, the signal accessor circuitry 524 obtains sensor data from at least one of the sensors 514, 516, 518. In some examples, the signal accessor circuitry 524 obtains sensor data associated with operations of the server 500, operations of the component devices 502, 504, 506 and/or operations of the fans 508, 510, 512. For example, the signal accessor circuitry 524 can obtain data indicative of sound associated with at least one of the component devices 502, 504, 506. Additionally or alternatively, the example signal accessor circuitry 524 can obtain data indicative of sound associated with at least one of the fans 508, 510, 512. In some examples, the signal accessor circuitry 524 can obtain data indicative of temperature metrics (e.g., heat dissipation, thermal resistance, thermal airflow, θJAs, etc.) associated with at least one of the component devices 502, 504, 506. Additionally or alternatively, the example signal accessor circuitry 524 can obtain data indicative of temperature metrics associated with at least one of the fans 508, 510, 512.

At block 1304, the example signal accessor circuitry 542 obtains data associated with an environment of the server 500. For examples, the example server 500 may be communicatively coupled to the external sensor 520 configured to obtain data associated with an environment of the server 500. In other examples, the external sensor 520 obtains data indicating an external perception of the sound generated by the server 500. For example, the external sensor 520 can detect how loud the server 500 is outside of an example housing/cover of the server 500. The example signal accessor circuitry 524 obtains sensor data from the sensor 520.

At block 1306, the example comparison circuitry 526 determines whether the noise output of the server 500 satisfies an example noise threshold. For example, if the example noise threshold is 65 dBA and the server noise output (e.g., sum of the noise output of the component devices 502, 504, 506, the noise output of at least one of the component devices 502, 504, 506, etc.) is 60 dB, then the comparison circuitry 526 can determine that the server noise output is less than the example noise threshold (e.g., 60 dBA<65 dBA). As such, the example comparison circuitry 526 determines that the example noise threshold is satisfied, and the process returns to block 1302. In some examples, the server noise output is 70 dBA. In such examples, the comparison circuitry 526 can determine that the server noise output is greater than the example noise threshold (e.g., 70 dBA>65 dBA). As such, the example comparison circuitry 526 determines that the example noise threshold is not satisfied, and the process proceeds to block 1308.

At block 1308, the example comparison circuitry 526 determines which operation(s) to adjust of the component devices 502, 504, 506, the fans 508, 510, 512, etc. In some examples, the comparison circuitry 526 determines which of the operation(s) to adjust based on the output of at least one of the sensors 514, 516, 518, 520. In some examples, the comparison circuitry 526 determines adjustment based on priority levels associated with the component devices 502, 504, 506. In some examples, the comparison circuitry 526 determines adjustment based on a time of day, a priority level of the at least one of the component devices 502, 504, 506, a thermal resistance measurement of the at least one of the component devices 502, 504, 506, an external input (e.g., a user/operator input), etc. In some examples, the comparison circuitry 526 determines adjustment based on thermal resistance metrics associated with the component devices 502, 504, 506.

At block 1310, the example adjustment circuitry 528 adjusts at least one of the operations. In some examples, the adjustment circuitry 528 adjusts at least one of the operations to satisfy an example noise threshold. The example adjustment circuitry 528 adjusts the operation of the server 500 based on the output of at least one of the sensors 514, 516, 518, 520. In some examples, the adjustment circuitry 528 adjusts the operation of at least one of the component devices 502, 504, 506 based on the output of at least one of the sensors 514, 516, 518, 520. In some examples, the adjustment circuitry 528 adjusts the operation of at least one of the component devices 502, 504, 506 based on priority levels associated with the component devices 502, 504, 506. For example, the adjustment circuitry 528 can adjust the operation of the component device 502 based on the component device 502 having a lower priority than the component device 504 and/or the component device 506. In some examples, the adjustment circuitry 528 can adjust the operation of at least one of the component devices 502, 504, 506 piecewise (e.g., in parts) based on a time of day, a priority level of the at least one of the component devices 502, 504, 506, a thermal resistance measurement of the at least one of the component devices 502, 504, 506, an external input (e.g., a user/operator input), etc. In some examples the adjustment circuitry 528 adjusts the operations of the component devices 502, 504, 506 based on thermal resistance metrics associated with the component devices 502, 504, 506. For example, the adjustment circuitry 528 can adjust the operation of the component device 504 based on the component device 504 generating more heat than the component device 506 and/or the component device 502. In some examples, the adjustment circuitry 528 notifies (e.g., alerts) an example Operating System (OS) (e.g., system software) of the adjusted operation. Then, the process ends.

FIG. 14 is a block diagram of an example programmable circuitry platform 1400 structured to execute and/or instantiate the example machine-readable instructions and/or the example operations of FIG. 13 to implement the noise mitigation circuitry 522 of FIG. 5. The programmable circuitry platform 1400 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1400 of the illustrated example includes programmable circuitry 1412. The programmable circuitry 1412 of the illustrated example is hardware. For example, the programmable circuitry 1412 can be implemented by one or more integrated circuits, logic circuits, FPGAs, microprocessors, CPUs, GPUs, DSPs, and/or microcontrollers from any desired family or manufacturer. The programmable circuitry 1412 may be implemented by one or more semiconductor based (e.g., silicon based) devices. In this example, the programmable circuitry 1412 implements example signal accessor circuitry 524, example comparison circuitry 526, and example adjustment circuitry 528.

The programmable circuitry 1412 of the illustrated example includes a local memory 1413 (e.g., a cache, registers, etc.). The programmable circuitry 1412 of the illustrated example is in communication with main memory 1414, 1416, which includes a volatile memory 1414 and a non-volatile memory 1416, by a bus 1418. The volatile memory 1414 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1416 may be implemented by flash memory and/or any other desired type of memory device. Access to the main memory 1414, 1416 of the illustrated example is controlled by a memory controller 1417. In some examples, the memory controller 1417 may be implemented by one or more integrated circuits, logic circuits, microcontrollers from any desired family or manufacturer, or any other type of circuitry to manage the flow of data going to and from the main memory 1414, 1416.

The programmable circuitry platform 1400 of the illustrated example also includes interface circuitry 1420. The interface circuitry 1420 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1422 are connected to the interface circuitry 1420. The input device(s) 1422 permit(s) a user (e.g., a human user, a machine user, etc.) to enter data and/or commands into the programmable circuitry 1412. The input device(s) 1422 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1424 are also connected to the interface circuitry 1420 of the illustrated example. The output device(s) 1424 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1420 of the illustrated example, thus, typically includes a graphics driver card, a graphics driver chip, and/or graphics processor circuitry such as a GPU.

The interface circuitry 1420 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1426. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1400 of the illustrated example also includes one or more mass storage discs or devices 1428 to store firmware, software, and/or data. Examples of such mass storage discs or devices 1428 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1432, which may be implemented by the machine readable instructions of FIG. 13, may be stored in the mass storage device 1428, in the volatile memory 1414, in the non-volatile memory 1416, and/or on at least one non-transitory computer readable storage medium such as a CD or DVD which may be removable.

FIG. 15 is a block diagram of an example implementation of the programmable circuitry 1412 of FIG. 14. In this example, the programmable circuitry 1412 of FIG. 14 is implemented by a microprocessor 1500. For example, the microprocessor 1500 may be a general-purpose microprocessor (e.g., general-purpose microprocessor circuitry). The microprocessor 1500 executes some or all of the machine-readable instructions of the flowchart of FIG. 13 to effectively instantiate the circuitry of FIG. 5 as logic circuits to perform operations corresponding to those machine readable instructions. In some such examples, the circuitry of FIG. 5 is instantiated by the hardware circuits of the microprocessor 1500 in combination with the machine-readable instructions. For example, the microprocessor 1500 may be implemented by multi-core hardware circuitry such as a CPU, a DSP, a GPU, an XPU, etc. Although it may include any number of example cores 1502 (e.g., 1 core), the microprocessor 1500 of this example is a multi-core semiconductor device including N cores. The cores 1502 of the microprocessor 1500 may operate independently or may cooperate to execute machine readable instructions. For example, machine code corresponding to a firmware program, an embedded software program, or a software program may be executed by one of the cores 1502 or may be executed by multiple ones of the cores 1502 at the same or different times. In some examples, the machine code corresponding to the firmware program, the embedded software program, or the software program is split into threads and executed in parallel by two or more of the cores 1502. The software program may correspond to a portion or all of the machine readable instructions and/or operations represented by the flowchart of FIG. 13.

The cores 1502 may communicate by a first example bus 1504. In some examples, the first bus 1504 may be implemented by a communication bus to effectuate communication associated with one(s) of the cores 1502. For example, the first bus 1504 may be implemented by at least one of an Inter-Integrated Circuit (I2C) bus, a Serial Peripheral Interface (SPI) bus, a PCI bus, or a PCIe bus. Additionally or alternatively, the first bus 1504 may be implemented by any other type of computing or electrical bus. The cores 1502 may obtain data, instructions, and/or signals from one or more external devices by example interface circuitry 1506. The cores 1502 may output data, instructions, and/or signals to the one or more external devices by the interface circuitry 1506. Although the cores 1502 of this example include example local memory 1520 (e.g., Level 1 (L1) cache that may be split into an L1 data cache and an L1 instruction cache), the microprocessor 1500 also includes example shared memory 1510 that may be shared by the cores (e.g., Level 2 (L2 cache)) for high-speed access to data and/or instructions. Data and/or instructions may be transferred (e.g., shared) by writing to and/or reading from the shared memory 1510. The local memory 1520 of each of the cores 1502 and the shared memory 1510 may be part of a hierarchy of storage devices including multiple levels of cache memory and the main memory (e.g., the main memory 1414, 1416 of FIG. 14). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1502 may be referred to as a CPU, DSP, GPU, etc., or any other type of hardware circuitry. Each core 1502 includes control unit circuitry 1514, arithmetic and logic (AL) circuitry (sometimes referred to as an ALU) 1516, a plurality of registers 1518, the local memory 1520, and a second example bus 1522. Other structures may be present. For example, each core 1502 may include vector unit circuitry, single instruction multiple data (SIMD) unit circuitry, load/store unit (LSU) circuitry, branch/jump unit circuitry, floating-point unit (FPU) circuitry, etc. The control unit circuitry 1514 includes semiconductor-based circuits structured to control (e.g., coordinate) data movement within the corresponding core 1502. The AL circuitry 1516 includes semiconductor-based circuits structured to perform one or more mathematic and/or logic operations on the data within the corresponding core 1502. The AL circuitry 1516 of some examples performs integer based operations. In other examples, the AL circuitry 1516 also performs floating-point operations. In yet other examples, the AL circuitry 1516 may include first AL circuitry that performs integer-based operations and second AL circuitry that performs floating-point operations. In some examples, the AL circuitry 1516 may be referred to as an Arithmetic Logic Unit (ALU).

The registers 1518 are semiconductor-based structures to store data and/or instructions such as results of one or more of the operations performed by the AL circuitry 1516 of the corresponding core 1502. For example, the registers 1518 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1518 may be arranged in a bank as shown in FIG. 15. Alternatively, the registers 1518 may be organized in any other arrangement, format, or structure, such as by being distributed throughout the core 1502 to shorten access time. The second bus 1522 may be implemented by at least one of an I2C bus, a SPI bus, a PCI bus, or a PCIe bus.

Each core 1502 and/or, more generally, the microprocessor 1500 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. he microprocessor 1500 is a semiconductor device fabricated to include many transistors interconnected to implement the structures described above in one or more integrated circuits (ICs) contained in one or more packages.

The microprocessor 1500 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1500, in the same chip package as the microprocessor 1500 and/or in one or more separate packages from the microprocessor 1500.

FIG. 16 is a block diagram of another example implementation of the programmable circuitry 1412 of FIG. 14. In this example, the programmable circuitry 1412 is implemented by FPGA circuitry 1600. For example, the FPGA circuitry 1600 may be implemented by an FPGA. The FPGA circuitry 1600 can be used, for example, to perform operations that could otherwise be performed by the example microprocessor 1500 of FIG. 15 executing corresponding machine readable instructions. However, once configured, the FPGA circuitry 1600 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1500 of FIG. 15 described above (which is a general purpose device that may be programmed to execute some or all of the machine readable instructions represented by the flowchart of FIG. 13 but whose interconnections and logic circuitry are fixed once fabricated), the FPGA circuitry 1600 of the example of FIG. 16 includes interconnections and logic circuitry that may be configured, structured, programmed, and/or interconnected in different ways after fabrication to instantiate, for example, some or all of the operations/functions corresponding to the machine readable instructions represented by the flowchart of FIG. 13. In particular, the FPGA circuitry 1600 may be thought of as an array of logic gates, interconnections, and switches. The switches can be programmed to change how the logic gates are interconnected by the interconnections, effectively forming one or more dedicated logic circuits (unless and until the FPGA circuitry 1600 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 13. As such, the FPGA circuitry 1600 may be configured and/or structured to effectively instantiate some or all of the operations/functions corresponding to the machine readable instructions of the flowchart of FIG. 13 as dedicated logic circuits to perform the operations/functions corresponding to those software instructions in a dedicated manner analogous to an ASIC. Therefore, the FPGA circuitry 1600 may perform the operations/functions corresponding to the some or all of the machine readable instructions of FIG. 13 faster than the general-purpose microprocessor can execute the same.

In the example of FIG. 16, the FPGA circuitry 1600 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1600 of FIG. 16 may access and/or load the binary file to cause the FPGA circuitry 1600 of FIG. 16 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1600 of FIG. 16 to cause configuration and/or structuring of the FPGA circuitry 1600 of FIG. 16, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1600 of FIG. 16 may access and/or load the binary file to cause the FPGA circuitry 1600 of FIG. 16 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1600 of FIG. 16 to cause configuration and/or structuring of the FPGA circuitry 1600 of FIG. 16, or portion(s) thereof.

The FPGA circuitry 1600 of FIG. 16, includes example input/output (I/O) circuitry 1602 to obtain and/or output data to/from example configuration circuitry 1604 and/or external hardware 1606. For example, the configuration circuitry 1604 may be implemented by interface circuitry that may obtain a binary file, which may be implemented by a bit stream, data, and/or machine-readable instructions, to configure the FPGA circuitry 1600, or portion(s) thereof. In some such examples, the configuration circuitry 1604 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1606 may be implemented by external hardware circuitry. For example, the external hardware 1606 may be implemented by the microprocessor 1500 of FIG. 15.

The FPGA circuitry 1600 also includes an array of example logic gate circuitry 1608, a plurality of example configurable interconnections 1610, and example storage circuitry 1612. The logic gate circuitry 1608 and the configurable interconnections 1610 are configurable to instantiate one or more operations/functions that may correspond to at least some of the machine readable instructions of FIG. 13 and/or other desired operations. The logic gate circuitry 1608 shown in FIG. 16 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1608 to enable configuration of the electrical structures and/or the logic gates to form circuits to perform desired operations/functions. The logic gate circuitry 1608 may include other electrical structures such as look-up tables (LUTs), registers (e.g., flip-flops or latches), multiplexers, etc.

The configurable interconnections 1610 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1608 to program desired logic circuits.

The storage circuitry 1612 of the illustrated example is structured to store result(s) of the one or more of the operations performed by corresponding logic gates. The storage circuitry 1612 may be implemented by registers or the like. In the illustrated example, the storage circuitry 1612 is distributed amongst the logic gate circuitry 1608 to facilitate access and increase execution speed.

The example FPGA circuitry 1600 of FIG. 16 also includes example dedicated operations circuitry 1614. In this example, the dedicated operations circuitry 1614 includes special purpose circuitry 1616 that may be invoked to implement commonly used functions to avoid the need to program those functions in the field. Examples of such special purpose circuitry 1616 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1600 may also include example general purpose programmable circuitry 1618 such as an example CPU 1620 and/or an example DSP 1622. Other general purpose programmable circuitry 1618 may additionally or alternatively be present such as a GPU, an XPU, etc., that can be programmed to perform other operations.

Although FIGS. 15 and 16 illustrate two example implementations of the programmable circuitry 1412 of FIG. 14, many other approaches are contemplated. For example, FPGA circuitry may include an on-board CPU, such as one or more of the example CPU 1620 of FIG. 15. Therefore, the programmable circuitry 1412 of FIG. 14 may additionally be implemented by combining at least the example microprocessor 1500 of FIG. 15 and the example FPGA circuitry 1600 of FIG. 16. In some such hybrid examples, one or more cores 1502 of FIG. 15 may execute a first portion of the machine readable instructions represented by the flowchart of FIG. 13 to perform first operation(s)/function(s), the FPGA circuitry 1600 of FIG. 16 may be configured and/or structured to perform second operation(s)/function(s) corresponding to a second portion of the machine readable instructions represented by the flowchart of FIG. 13, and/or an ASIC may be configured and/or structured to perform third operation(s)/function(s) corresponding to a third portion of the machine readable instructions represented by the flowchart of FIG. 13.

It should be understood that some or all of the circuitry of FIG. 5 may, thus, be instantiated at the same or different times. For example, same and/or different portion(s) of the microprocessor 1500 of FIG. 15 may be programmed to execute portion(s) of machine-readable instructions at the same and/or different times. In some examples, same and/or different portion(s) of the FPGA circuitry 1600 of FIG. 16 may be configured and/or structured to perform operations/functions corresponding to portion(s) of machine-readable instructions at the same and/or different times.

In some examples, some or all of the circuitry of FIG. 5 may be instantiated, for example, in one or more threads executing concurrently and/or in series. For example, the microprocessor 1500 of FIG. 15 may execute machine readable instructions in one or more threads executing concurrently and/or in series. In some examples, the FPGA circuitry 1600 of FIG. 16 may be configured and/or structured to carry out operations/functions concurrently and/or in series. Moreover, in some examples, some or all of the circuitry of FIG. 5 may be implemented within one or more virtual machines and/or containers executing on the microprocessor 1500 of FIG. 15.

In some examples, the programmable circuitry 1412 of FIG. 14 may be in one or more packages. For example, the microprocessor 1500 of FIG. 15 and/or the FPGA circuitry 1600 of FIG. 16 may be in one or more packages. In some examples, an XPU may be implemented by the programmable circuitry 1412 of FIG. 14, which may be in one or more packages. For example, the XPU may include a CPU (e.g., the microprocessor 1500 of FIG. 15, the CPU 1620 of FIG. 16, etc.) in one package, a DSP (e.g., the DSP 1622 of FIG. 16) in another package, a GPU in yet another package, and an FPGA (e.g., the FPGA circuitry 1600 of FIG. 16) in still yet another package.

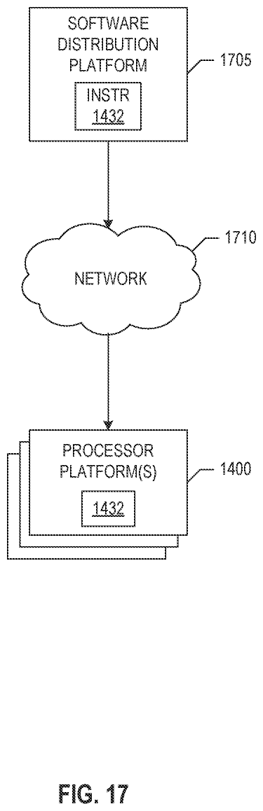

A block diagram illustrating an example software distribution platform 1705 to distribute software such as the example machine readable instructions 1432 of FIG. 14 to other hardware devices (e.g., hardware devices owned and/or operated by third parties from the owner and/or operator of the software distribution platform) is illustrated in FIG. 17. The example software distribution platform 1705 may be implemented by any computer server, data facility, cloud service, etc., capable of storing and transmitting software to other computing devices. The third parties may be customers of the entity owning and/or operating the software distribution platform 1705. For example, the entity that owns and/or operates the software distribution platform 1705 may be a developer, a seller, and/or a licensor of software such as the example machine readable instructions 1432 of FIG. 14. The third parties may be consumers, users, retailers, OEMs, etc., who purchase and/or license the software for use and/or re-sale and/or sub-licensing. In the illustrated example, the software distribution platform 1705 includes one or more servers and one or more storage devices. The storage devices store the machine readable instructions 1432, which may correspond to the example machine readable instructions of FIG. 13, as described above. The one or more servers of the example software distribution platform 1705 are in communication with an example network 1710, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1432 from the software distribution platform 1705. For example, the software, which may correspond to the example machine readable instructions of FIG. 13, may be downloaded to the example programmable circuitry platform 1400, which is to execute the machine readable instructions 1432 to implement the noise mitigation circuitry 522. In some examples, one or more servers of the software distribution platform 1705 periodically offer, transmit, and/or force updates to the software (e.g., the example machine readable instructions 1432 of FIG. 14) to ensure improvements, patches, updates, etc., are distributed and applied to the software at the end user devices. Although referred to as software above, the distributed “software” could alternatively be firmware.

From the foregoing, it will be appreciated that example systems, methods, apparatus, and articles of manufacture have been disclosed that enable an example server to dynamically (e.g., automatically) adjust system configuration parameters (e.g., fan operations) to control system noise emitted from electronic components of the server. Examples disclosed herein control the noise characteristics of example servers for improved human perception. Further, examples disclosed herein mitigate noise of an example server while maintaining higher priority operations of the server.

Disclosed systems, methods, apparatus, and articles of manufacture improve the efficiency of using a computing device by adjusting the operations of example component devices based on priority levels corresponding to the component devices. As such, examples disclosed herein can reduce operations of low priority component devices and maintain operations of high priority components devices. Examples disclosed herein enable example servers to control noise output based on noise levels of the environment. For example, examples disclosed herein utilize sensors to dynamically monitor a noise level of an example surrounding environment such that the example server can reduce noise levels to below that of the surrounding environment. Disclosed systems, methods, apparatus, and articles of manufacture are accordingly directed to one or more improvement(s) in the operation of a machine such as a computer or other electronic and/or mechanical device.

Example 1 includes a server comprising a housing to at least partially contain components of the server, a transducer to output an indication of noise detected outside of the housing, machine readable instructions, and programmable circuitry to at least one of instantiate or execute the machine readable instructions to adjust an operation of the server based on the output of the transducer to reduce noise.

Example 2 includes the server of example 1, wherein the programmable circuitry is to at least one of instantiate or execute instructions to obtain data indicative of sound associated with an environment of the server, compare the output of the transducer to the data, and adjust the operation of the server based on the comparison.

Example 3 includes the server of example 1, wherein the indication is a first signal, wherein the programmable circuitry is to at least one of instantiate or execute instructions to obtain data indicative of sound associated with a component device of the server, the transducer to output a second signal associated with operation of the component device, and adjust the operation of the component device based on the output of the second signal to reduce noise.

Example 4 includes the server of example 3, wherein the programmable circuitry is to at least one of instantiate or execute the instructions to adjust the operation of the component device to a first operational level at a first time, and adjust the operation of the component device to a second operational level at a second time, the second operational level less than the first operational level, the second time subsequent to the first time.

Example 5 includes the server of example 3, wherein the component device is a first component device and the data is first data, wherein the programmable circuitry is to at least one of instantiate or execute the instructions to obtain second data indicative of sound associated with a second component device of the server, the transducer to output a third signal associated with operation of the second component device, compare the operation of the first component device to the operation of the second component device, and adjust the operation of the second component device based on the second component device having a lower priority than the first component device.

Example 6 includes the server of example 3, wherein the component device is a first component device, wherein the programmable circuitry is to at least one of instantiate or execute the instructions to obtain third data indicative of sound associated with a second component device of the server, the transducer to output a third signal associated with operation of the second component device, and adjust the operation of the second component device based on the first component device generating more heat than the second component device.

Example 7 includes the server of example 1, wherein the programmable circuitry is to adjust the operation of the server by adjusting a setting of at least one fan, the housing enclosing the at least one fan.

Example 8 includes the server of example 1, wherein the programmable circuitry is to adjust the operation of the server based on at least one of a time of day or a location of the server.

Example 9 includes the server of claim 1, wherein the programmable circuitry is to notify an operating system (OS) of the adjusted operation.

Example 10 includes a non-transitory machine readable storage medium comprising instructions to cause programmable circuitry to at least access an indication of noise detected outside of a housing of a computing device, the noise obtained by a transducer associated with the computing device, and adjust the operation of the computing device based on the indication to reduce noise.

Example 11 includes the non-transitory machine readable medium of example 10, wherein the instructions to cause programmable circuitry to obtain data indicative of sound associated with an environment of the computing device, compare the indication to the data, and adjust an operation of the computing device based on the comparison.

Example 12 includes the non-transitory machine readable medium of example 10, wherein the indication is a first indication, wherein the instructions cause programmable circuitry to obtain data indicative of sound associated with a component device of the computing device, the transducer to output a second indication associated with operation of the component device, and adjust the operation of the component device based on the output of the second indication to reduce noise.

Example 13 includes the non-transitory machine readable medium of example 12, wherein the instructions cause programmable circuitry to adjust the operation of the component device to a first operational level at a first time, and adjust the operation of the component device to a second operational level at a second time, the second operational level less than the first operational level, the second time subsequent to the first time.

Example 14 includes the non-transitory machine readable medium of example 12, wherein the component device is a first component device and the data is first data, wherein instructions cause the programmable circuitry to obtain second data indicative of sound associated with a second component device of the computing device, the transducer to output a third signal associated with operation of the second component device, compare the operation of the first component device to the operation of the second component device, and adjust the operation of the second component device based on the second component device having a lower priority than the first component device.

Example 15 includes the non-transitory machine readable medium of example 12, wherein the component device is a first component device, wherein the instructions cause the programmable circuitry to obtain third data indicative of sound associated with a second component device of the computing device, the transducer to output a third signal associated with operation of the second component device, and adjust the operation of the second component device based on the first component device generating more heat than the second component device.

Example 16 includes the non-transitory machine readable medium of example 10, wherein instructions cause the programmable circuitry to adjust the operation of the computing device by adjusting a setting of at least one fan, the at least one fan cooling the computing device.

Example 17 includes the non-transitory machine readable medium of example 10, wherein the instructions cause the programmable circuitry to adjust the operation of the computing device based on at least one of a time of day or a location of the computing device.

Example 18 includes a server comprising a housing, computing devices associated with operations of the server, first transducers coupled to the computing devices, the first transducers positioned within the housing, second transducers coupled to the server, the second transducers positioned on an external surface of the housing, machine readable instructions, and programmable circuitry to instantiate or execute the machine readable instructions to adjust at least one of the operations to reduce a noise output of the server, the adjustment based on indications associated with the second transducers.

Example 19 includes the server of example 18, wherein the indications include at least one of a decibel (dB) level, a temperature metric, or a measurement of thermal resistance.

Example 20 includes the server of example 18, wherein the computing devices are coupled to a cooling system, the first transducers accessing data associated with the cooling system.

Example 21 includes the server of example 20, wherein the at least one of the operations is associated with the cooling system.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. A server comprising:
a housing to at least partially contain components of the server;
a transducer to output an indication of noise detected outside of the housing;
machine readable instructions; and
programmable circuitry to at least one of instantiate or execute the machine readable instructions to adjust an operation of the server based on the output of the transducer to reduce noise.

2. The server of claim 1, wherein the programmable circuitry is to at least one of instantiate or execute instructions to:
obtain data indicative of sound associated with an environment of the server;
compare the output of the transducer to the data; and
adjust the operation of the server based on the comparison.

3. The server of claim 1, wherein the indication is a first signal, wherein the programmable circuitry is to at least one of instantiate or execute instructions to:
obtain data indicative of sound associated with a component device of the server, the transducer to output a second signal associated with operation of the component device; and
adjust the operation of the component device based on the output of the second signal to reduce noise.

4. The server of claim 3, wherein the programmable circuitry is to at least one of instantiate or execute the instructions to:
adjust the operation of the component device to a first operational level at a first time; and
adjust the operation of the component device to a second operational level at a second time, the second operational level less than the first operational level, the second time subsequent to the first time.

5. The server of claim 3, wherein the component device is a first component device and the data is first data, wherein the programmable circuitry is to at least one of instantiate or execute the instructions to:
obtain second data indicative of sound associated with a second component device of the server, the transducer to output a third signal associated with operation of the second component device;
compare the operation of the first component device to the operation of the second component device; and
adjust the operation of the second component device based on the second component device having a lower priority than the first component device.

6. The server of claim 3, wherein the component device is a first component device, wherein the programmable circuitry is to at least one of instantiate or execute the instructions to:
obtain third data indicative of sound associated with a second component device of the server, the transducer to output a third signal associated with operation of the second component device; and
adjust the operation of the second component device based on the first component device generating more heat than the second component device.

7. The server of claim 1, wherein the programmable circuitry is to adjust the operation of the server by adjusting a setting of at least one fan, the housing enclosing the at least one fan.

8. The server of claim 1, wherein the programmable circuitry is to adjust the operation of the server based on at least one of a time of day or a location of the server.

9. (canceled)

10. A non-transitory machine readable storage medium comprising instructions to cause programmable circuitry to at least:
access an indication of noise detected outside of a housing of a computing device, the noise obtained by a transducer associated with the computing device; and
adjust an operation of the computing device based on the indication to reduce noise.

11. The non-transitory machine readable medium of claim 10, wherein the instructions to cause programmable circuitry to:
obtain data indicative of sound associated with an environment of the computing device;
compare the indication to the data; and
adjust the operation of the computing device based on the comparison.

12. The non-transitory machine readable medium of claim 10, wherein the indication is a first indication, wherein the instructions cause programmable circuitry to:
obtain data indicative of sound associated with a component device of the computing device, the transducer to output a second indication associated with operation of the component device; and
adjust the operation of the component device based on the output of the second indication to reduce noise.

13. The non-transitory machine readable medium of claim 12, wherein the instructions cause programmable circuitry to:
adjust the operation of the component device to a first operational level at a first time; and
adjust the operation of the component device to a second operational level at a second time, the second operational level less than the first operational level, the second time subsequent to the first time.

14. The non-transitory machine readable medium of claim 12, wherein the component device is a first component device and the data is first data, wherein instructions cause the programmable circuitry to:
obtain second data indicative of sound associated with a second component device of the computing device, the transducer to output a third signal associated with operation of the second component device;
compare the operation of the first component device to the operation of the second component device; and
adjust the operation of the second component device based on the second component device having a lower priority than the first component device.

15. The non-transitory machine readable medium of claim 12, wherein the component device is a first component device, wherein the instructions cause the programmable circuitry to:
obtain third data indicative of sound associated with a second component device of the computing device, the transducer to output a third signal associated with operation of the second component device; and
adjust the operation of the second component device based on the first component device generating more heat than the second component device.

16. The non-transitory machine readable medium of claim 10, wherein instructions cause the programmable circuitry to adjust the operation of the computing device by adjusting a setting of at least one fan, the at least one fan cooling the computing device.

17. The non-transitory machine readable medium of claim 10, wherein the instructions cause the programmable circuitry to adjust the operation of the computing device based on at least one of a time of day or a location of the computing device.

18. A server comprising:
a housing;
computing devices associated with operations of the server;
first transducers coupled to the computing devices, the first transducers positioned within the housing;
second transducers coupled to the server, the second transducers positioned on an external surface of the housing;
machine readable instructions; and
programmable circuitry to instantiate or execute the machine readable instructions to adjust at least one of the operations to reduce a noise output of the server, the adjustment based on indications associated with the second transducers.

19. The server of claim 18, wherein the indications include at least one of a decibel (dB) level, a temperature metric, or a measurement of thermal resistance.

20. The server of claim 18, wherein the computing devices are coupled to a cooling system, the first transducers accessing data associated with the cooling system.

21. The server of claim 20, wherein the at least one of the operations is associated with the cooling system.
